(19) United States
(12) Patent Application Publication
(10) Pub. No.: US 2026/0271779 A1
(43) Pub. Date: Sep. 10, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Jia LIU, Yokohama Kanagawa (JP); Toshihiro TSUJIMURA, Tokyo (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/359,831

(22) Filed: Oct. 16, 2025

(30) Foreign Application Priority Data
Mar. 7, 2025 (JP) 2025-036409

(51) Int. Cl. H01L 23/16; H01L 23/00; H01L 25/07; H01L 25/16; H10D 80/20; H10F 39/10; H10F 39/95; H10H 29/20

(52) U.S. Cl. CPC H10W 76/40; H10D 80/251; H10F 39/107; H10F 39/95; H10H 29/20; H10W 90/00; H10W 90/753

(57) ABSTRACT

According to one embodiment, a semiconductor device includes first and second transistors, a light emitter, a light receiver, first and second spacers. The first transistor is provided above a first surface of a board. The second transistor is provided above the first surface of the board and arranged in a first direction along the first surface of the board with respect to the first transistor. The light emitter is provided above the first surface of the board, and arranged in a second direction perpendicular to the first direction and along the first surface with respect to the first and second transistors. The light receiver is provided above the first and second transistors and the light emitter. The first spacer is provided between the first transistor and the light receiver, and electrically connects them. The second spacer is provided between the second transistor and the light receiver, and electrically connects them.

### CROSS-REFERENCE TO RELATED APPLICATIONS

This application is based upon and claims the benefit of priority from Japanese Patent Application No. 2025-036409, filed Mar. 7, 2025, the entire contents of which are incorporated herein by reference.

### FIELD

Embodiments described herein relate generally to a semiconductor device.

### BACKGROUND

As a semiconductor device, a photo relay device is known. The photo relay device is a semiconductor relay including a light emitter and a light receiver. The photo relay device is a contactless relay, and is used to transmit an AC signal or a DC signal.

### BRIEF DESCRIPTION OF THE DRAWINGS

FIG. 1 is a circuit diagram showing a circuit configuration of a semiconductor device according to a first embodiment.

FIG. 2 is a perspective view showing an example of an external shape of the semiconductor device according to the first embodiment.

FIG. 3 is a top view showing a structure of the semiconductor device according to the first embodiment.

FIGS. 4 to 6 are sectional views showing the structure of the semiconductor device according to the first embodiment.

FIG. 7 is a top view showing a structure of a semiconductor device according to a first modification of the first embodiment.

FIG. 8 is a sectional view showing the structure of the semiconductor device according to the first modification of the first embodiment.

FIG. 9 is a top view showing a structure of a semiconductor device according to a second modification of the first embodiment.

FIG. 10 is a sectional view showing the structure of the semiconductor device according to the second modification of the first embodiment.

FIG. 11 is a top view showing a structure of a semiconductor device according to a second embodiment.

FIGS. 12 and 13 are sectional views showing the structure of the semiconductor device according to the second embodiment.

FIG. 14 is a top view showing a structure of a semiconductor device according to a first modification of the second embodiment.

FIG. 15 is a sectional view showing the structure of the semiconductor device according to the first modification of the second embodiment.

FIG. 16 is a top view showing a structure of a semiconductor device according to a second modification of the second embodiment.

FIG. 17 is a sectional view showing the structure of the semiconductor device according to the second modification of the second embodiment.

FIG. 18 is a top view showing a structure of a semiconductor device according to a third embodiment.

FIGS. 19 to 21 are sectional views showing the structure of the semiconductor device according to the third embodiment.

FIG. 22 is a top view showing a structure of a semiconductor device according to a modification of the third embodiment.

FIG. 23 is a sectional view showing the structure of the semiconductor device according to the modification of the third embodiment.

### DETAILED DESCRIPTION

In general, according to one embodiment, a semiconductor device includes a first transistor, a second transistor, a light emitter, a light receiver, a first spacer and a second spacer. The first transistor is provided above a first surface of a board. The second transistor is provided above the first surface of the board, and arranged in a first direction along the first surface of the board with respect to the first transistor. The light emitter is provided above the first surface of the board, and arranged in a second direction perpendicular to the first direction and along the first surface of the board with respect to the first transistor and the second transistor. The light receiver is provided above the first transistor, the second transistor, and the light emitter. The first spacer is provided between the first transistor and the light receiver, and electrically connects the first transistor and the light receiver. The second spacer is provided between the second transistor and the light receiver, and electrically connects the second transistor and the light receiver.

Embodiments will be described below with reference to the accompanying drawings. In the following description, the same reference numerals denote constituent elements having the same functions and configurations. The embodiments to be described below exemplify devices and methods for embodying the technical concepts of the embodiments, and do not limit the materials, shapes, structures, arrangements, and the like of the components to those to be described below.

The drawings used for explanation are schematic or conceptual. The dimensions and ratios of each drawing are not always the same as the actual ones. In some drawings showing structures, an XYZ orthogonal coordinate system is used. The X-axis extends in the X direction. The Y-axis extends in the Y direction. The Z-axis extends in the Z direction. The X and Y directions are directions orthogonal to each other. The Z direction is orthogonal to each of the X and Y directions, and corresponds to the vertical direction with respect to the surface of a substrate. The side having a larger coordinate on the X-axis (X direction), the Y-axis (Y direction), or the Z-axis (Z direction) may be referred to as a plus direction, and the side having a smaller coordinate may be referred to as a minus direction. The plus and minus directions on the Z-axis may be referred to as the upper and lower sides, respectively. The plus and minus directions on the X- or Y-axis may be referred to as the right and left sides, respectively.

A semiconductor device according to an embodiment will be described below. The semiconductor device according to the embodiment is, for example, a photo relay device.

### 1. First Embodiment

A photo relay device as a semiconductor device according to the first embodiment will be described.

### 1.1. Circuit Configuration

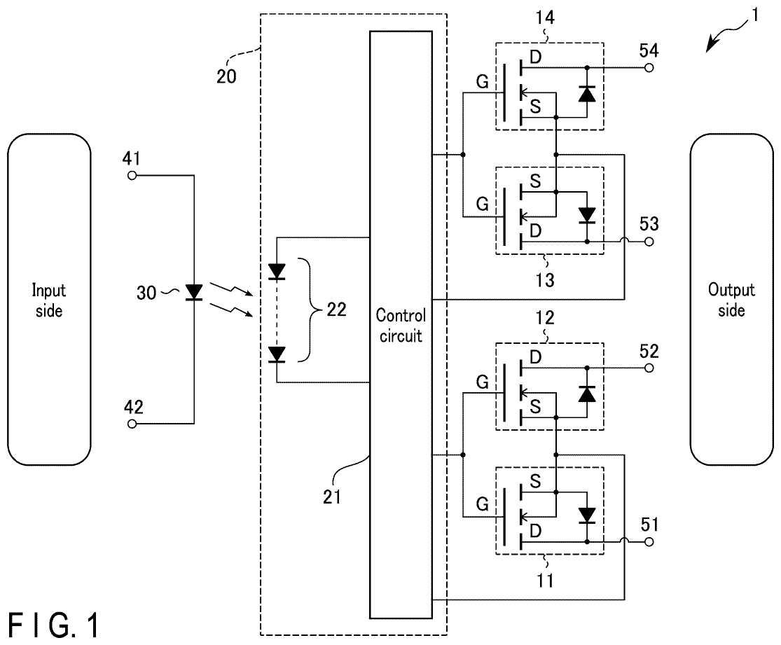

First, with reference to FIG. 1, the circuit configuration of a photo relay device 1 according to the first embodiment will be described. FIG. 1 is a circuit diagram showing the circuit configuration of the photo relay device 1 according to the first embodiment.

The photo relay device 1 includes, as circuit elements, four transistors 11, 12, 13, and 14, a light receiver 20, and a light emitter 30. The photo relay device 1 further includes terminals 41 and 42, and terminals 51, 52, 53, and 54. Here, since the photo relay device 1 supports differential communication, it includes four transistors 11, 12, 13, and 14 and four terminals 51, 52, 53, and 54. Note that if a photo relay device supports single communication, it only requires to include, for example, two transistors 11 and 12 and two terminals 51 and 52. A photo relay device supporting signal communication will be described in a modification to be described later.

Each of the transistors 11, 12, 13, and 14 is, for example, a Metal Oxide Semiconductor Field Effect Transistor (MOSFET), and more specifically, an enhancement n channel MOSFET.

The drains of the transistors 11, 12, 13, and 14 are connected to the terminals 51, 52, 53, and 54, respectively. The sources of the transistors 11 and 12, and the sources of the transistors 13 and 14 are connected to terminals of a control circuit 21 in the light receiver 20. The gates of the transistors 11 and 12 and the gates of the transistors 13 and 14 are connected to terminals of the control circuit 21 in the light receiver 20.

The transistors 11, 12, 13, and 14 are used to control signals to be transmitted. For example, a first signal Sp is transmitted via the transistors 11 and 12, and a second signal Sn, which is an inverted signal of the first signal Sp, is transmitted via the transistors 13 and 14.

The light receiver 20 is, for example, a photo Diode Array (PDA) including the control circuit 21, and several to several ten photodiodes 22 connected in series. The both terminals of the photodiodes 22 connected in series are connected to the control circuit 21. The control circuit 21 uses the voltage applied from the photodiodes 22 as a power supply voltage to control the transistors 11, 12, 13, and 14. Note that the light receiver 20 may be a photo transistor or the like instead of the photodiode.

The light emitter 30 is, for example, a Light Emitting Diode (LED). The light emitter 30 is connected to the terminals 41 and 42. A signal to be transmitted using the photo relay device 1 is input to the terminals 41 and 42.

In the photo relay device 1, if a sufficient potential difference is generated between the terminals 41 and 42, the light emitter 30 transitions to an ON state (light emission state). When the light emitter 30 transitions to the ON state, the light emitter 30 emits light with respect to the light receiver 20. The light receiver 20 receives the light emitted from the light emitter 30, and generates, for example, a voltage of 7 V to 10-odd V. This sets the transistors 11 and 12 or the transistors 13 and 14 in an ON state, and the terminals 51 and 52 or the terminals 53 and 54 are connected to each other. On the other hand, when the potential difference between the terminals 41 and 42 decreases and the light emitter 30 transitions to an OFF state (non-light emission state), the transistors 11 and 12 or the transistors 13 and 14 are set in an OFF state, and the terminals 51 and 52 or the terminals 53 and 54 are insulated from each other.

### 1.2. Structure

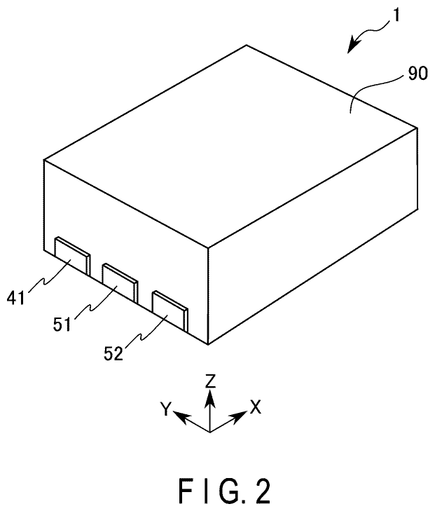

Next, with reference to FIGS. 2, 3, 4, 5, and 6, the structure of the photo relay device 1 according to the first embodiment will be described.

FIG. 2 is a perspective view showing an example of the external shape of the photo relay device 1 according to the first embodiment. The photo relay device 1 includes the transistors 11, 12, 13, and 14, the light receiver 20, and the light emitter 30 on a board (not shown) that are covered with a resin member 90. That is, the photo relay device 1 has a package structure in which the transistors 11, 12, 13, and 14, the light receiver 20, and the light emitter 30 provided on a board are sealed with the resin member 90. For example, the terminals 41, 51, and 52 are provided in one end of the resin member 90 in the X direction, and the terminals 42, 53, and 54 (not shown) are provided in the other end of the resin member 90.

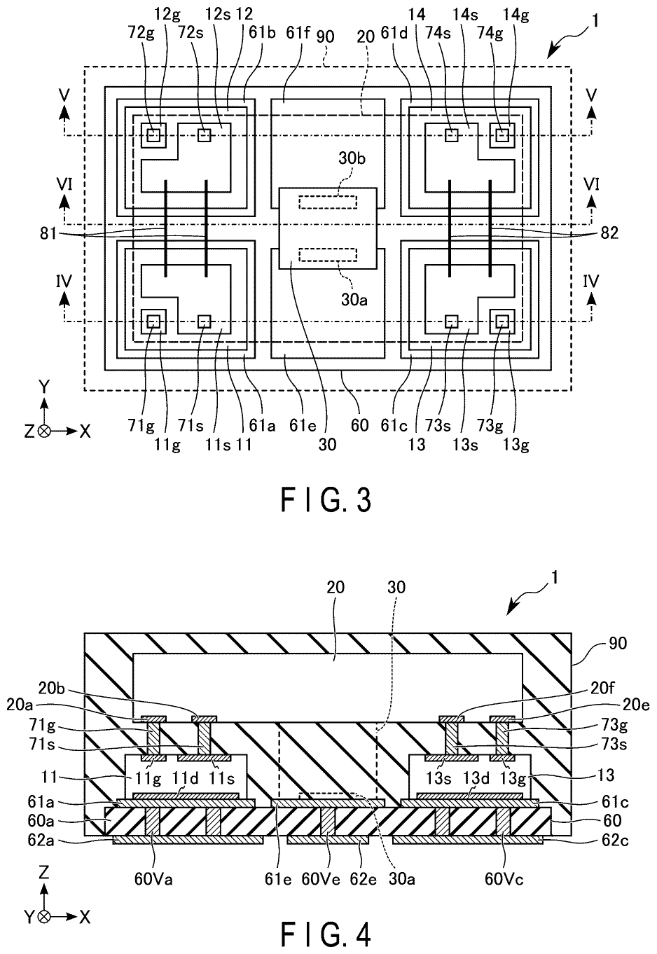

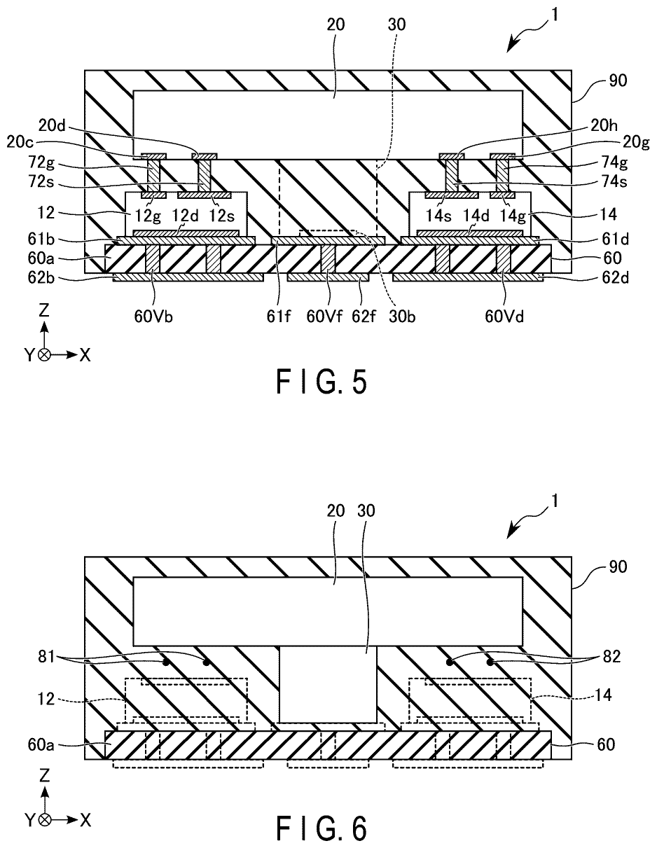

FIG. 3 is a top view showing the structure of the photo relay device 1 according to the first embodiment. FIG. 3 shows the structure of the photo relay device 1 when viewed through the resin member 90 and the light receiver 20 from the upper surface side (or the Z direction) in FIG. 2. FIGS. 4 to 6 are sectional views showing the structure of the photo relay device 1 according to the first embodiment. FIG. 4 shows the sectional structure of the photo relay device 1 taken along a line IV-IV in FIG. 3. FIG. 5 shows the sectional structure of the photo relay device 1 taken along a line V-V in FIG. 3. FIG. 6 shows the sectional structure of the photo relay device 1 taken along a line VI-VI in FIG. 3.

The photo relay device 1 includes spacers 71g, 71s, 72g, 72s, 73g, 73s, 74g, and 74s, and bonding wires 81 and 82, in addition to the transistors 11, 12, 13, and 14, the light receiver 20, the light emitter 30, a board 60, and the resin member 90.

As shown in FIG. 3, each of the transistors 11, 12, 13, and 14 has, for example, a rectangular chip shape (or package shape) when viewed from above. Each of the transistors 11, 12, 13, and 14 is, for example, a vertical MOSFET.

The transistor 11 includes a gate electrode 11g, a source electrode 11s, and a drain electrode 11d. The gate electrode 11g and the source electrode 11s are provided in the first surface (or upper surface) of the transistor 11. The drain electrode 11d is provided in the second surface (or lower surface) of the transistor 11.

This also applies to the other transistors 12, 13, and 14. The transistor 12 includes a gate electrode 12g, a source electrode 12s, and a drain electrode 12d. The gate electrode 12g and the source electrode 12s are provided in the first surface (or upper surface) of the transistor 12. The drain electrode 12d is provided in the second surface (or lower surface) of the transistor 12.

The transistor 13 includes a gate electrode 13g, a source electrode 13s, and a drain electrode 13d. The gate electrode 13g and the source electrode 13s are provided in the first surface (or upper surface) of the transistor 13. The drain electrode 13d is provided in the second surface (or lower surface) of the transistor 13.

The transistor 14 includes a gate electrode 14g, a source electrode 14s, and a drain electrode 14d. The gate electrode 14g and the source electrode 14s are provided in the first surface (or upper surface) of the transistor 14. The drain electrode 14d is provided in the second surface (or lower surface) of the transistor 14.

The light receiver 20 has, for example, a rectangular chip shape (or package shape) when viewed from above. The light receiver 20 includes, for example, a light receiving surface and eight electrodes 20a, 20b, 20c, 20d, 20e, 20f, 20g, and 20h. The light receiving surface and the electrodes 20a, 20b, 20c, 20d, 20e, 20f, 20g, and 20h are provided in the lower surface of the light receiver 20. The electrodes 20a, 20b, 20c, 20d, 20e, 20f, 20g, and 20h contain, for example, a conductive material such as copper.

The light emitter 30 has, for example, a rectangular chip shape (or package shape) when viewed from above. The light emitter 30 includes, for example, a light emitting surface and two electrodes 30a and 30b. The light emitting surface is provided in the upper surface of the light emitter 30. The electrodes 30a and 30b are provided in the lower surface of the light emitter 30. The electrodes 30a and 30b contain, for example, a conductive material such as copper.

The board 60 is, for example, a Double-sided wiring board (or a Double-sided printed circuit board) including an insulating layer 60a, a plurality of pads (and/or wirings or conductive layers) 61 and 62, and a plurality of vias 60V.

The plurality of pads 61 include pads 61a, 61b, 61c, 61d, 61e, and 61f. The plurality of pads 62 include pads 62a, 62b, 62c, 62d, 62e, and 62f. The plurality of vias 60V include vias 60Va, 60Vb, 60Vc, 60Vd, 60Ve, and 60Vf.

The pad 61 is provided on the first surface (or upper surface) of the board 60 (or the insulating layer 60a). The pad 62 is provided on the second surface (or lower surface) of the board 60 (or the insulating layer 60a). The via 60V is provided in the insulating layer 60a. The via 60V is provided to extend through the insulating layer 60a between the pad 61 on the first surface and the pad 62 on the second surface, and electrically connects the pad 61 on the first surface and the pad 62 on the second surface. The pads 61 and 62 contain, for example, a conductive material such as copper. The via 60V contain, for example, a conductive material such as copper.

The board 60 is, for example, Flexible Printed Circuits (FPC), a resin substrate, or a polyimide substrate. Here, a case where the board 60 is a double-sided wiring board is shown, but a multilayered wiring board in which multiple layers of pads and wirings are arranged in the insulating layer 60a may be used.

As shown in FIG. 4, the transistors 11, 12, 13, and 14 are provided on the board 60. The transistors 11 and 12 are arrayed in the Y direction. Similarly, the transistors 13 and 14 are arrayed in the Y direction.

The transistor 13 is arranged in the X direction with respect to the transistor 11. The transistor 14 is arranged in the X direction with respect to the transistor 12. In other words, the transistor 11 and the transistor 13 are arranged in line symmetry with respect to a line along the Y direction. The transistor 12 and the transistor 14 are arranged in line symmetry with respect to a line along the Y direction.

The light emitter 30 is provided on the board 60. The light emitter 30 is arranged between the transistors 11 and 12 and the transistors 13 and 14 in the X direction. The light emitter 30 is provided above the first surface of the board 60, and arranged in the X direction perpendicular to the Y direction and along the first surface of the board 60 with respect to the transistor 11 and the transistor 12. The light emitter 30 includes a light emitting surface in its upper surface.

The light receiver 20 is provided above (that is, in the Z direction) the transistors 11, 12, 13, and 14 and the light emitter 30. When viewed from above, the light receiver 20 partially or entirely overlaps the transistors 11, 12, 13, and 14 and the light emitter 30. The light receiver 20 includes a light receiving surface in its lower surface. The light receiving surface of the light receiver 20 is arranged to face the light emitting surface of the light emitter 30.

Spacers 71g and 71s are provided between the transistor 11 and the light receiver 20. This also applies to the other transistors 12 to 14 and the light receiver 20. Spacers 72g and 72s are provided between the transistor 12 and the light receiver 20. Spacers 73g and 73s are provided between the transistor 13 and the light receiver 20. Spacers 74g and 74s are provided between the transistor 14 and the light receiver 20. The spacers 71g, 71s, 72g, 72s, 73g, 73s, 74g, and 74s keep the spacings between the transistors 11, 12, 13, and 14 and the light receiver 20 to a predetermined distance, respectively. The spacers 71g, 71s, 72g, 72s, 73g, 73s, 74g, and 74s electrically connect the transistors 11, 12, 13, and 14 to the light receiver 20, respectively. The spacers 71g, 71s, 72g, 72s, 73g, 73s, 74g, and 74s are conductive members, and contain, for example, copper or an alloy. The spacers 71g, 71s, 72g, 72s, 73g, 73s, 74g and 74s are approximately equal in length in the Z direction.

The bonding wire 81 is provided between the transistor 11 and the transistor 12. One end of the bonding wire 81 is connected to the transistor 11, and the other end of the bonding wire 81 is connected to the transistor 12. The bonding wire 81 electrically connects the transistor 11 and the transistor 12.

The bonding wire 82 is provided between the transistor 13 and the transistor 14. One end of the bonding wire 82 is connected to the transistor 13, and the other end of the bonding wire 82 is connected to the transistor 14. The bonding wire 82 electrically connects the transistor 13 and the transistor 14. The bonding wires 81 and 82 are conductive members, and contain a metal such as gold, aluminum, or copper.

With reference to FIGS. 3, 4, 5, and 6, the structure of the photo relay device 1 will be described in detail.

The structures of the transistor 11, the transistor 12, and the light receiver 20 are as described below.

As shown in FIG. 4, the spacer 71g is provided between the gate electrode 11g of the transistor 11 and the electrode 20a of the light receiver 20. The spacer 71g is connected to the gate electrode 11g and the electrode 20a by, for example, a connecting member (for example, a silver paste or a solder). With this, the electrode 20a of the light receiver 20 is electrically connected to the gate electrode 11g of the transistor 11 via the spacer 71g.

The spacer 71s is provided between the source electrode 11s of the transistor 11 and the electrode 20b of the light receiver 20. The spacer 71s is connected to the source electrode 11s and the electrode 20b by, for example, a connecting member. With this, the electrode 20b of the light receiver 20 is electrically connected to the source electrode 11s of the transistor 11 via the spacer 71s.

The drain electrode 11d of the transistor 11 is connected to the pad 61a of the board 60 by, for example, a connecting member (for example, a silver paste or a solder). The via 60Va is provided in the insulating layer 60a between the pad 61a and the pad 62a. The via 60Va electrically connects the pad 61a and the pad 62a. The pad 62a corresponds to the terminal 51 shown in the circuit diagram of FIG. 1. With this, the drain electrode 11d of the transistor 11 is electrically connected to the terminal 51 via the pad 61a and the via 60Va.

As shown in FIG. 5, the spacer 72g is provided between the gate electrode 12g of the transistor 12 and the electrode 20c of the light receiver 20. The spacer 72g is connected to the gate electrode 12g and the electrode 20c by, for example, a connecting member. With this, the electrode 20c of the light receiver 20 is electrically connected to the gate electrode 12g of the transistor 12 via the spacer 72g.

The spacer 72s is provided between the source electrode 12s of the transistor 12 and the electrode 20d of the light receiver 20. The spacer 72s is connected to the source electrode 12s and the electrode 20d by, for example, a connecting member. With this, the electrode 20d of the light receiver 20 is electrically connected to the source electrode 12s of the transistor 12 via the spacer 72s.

The drain electrode 12d of the transistor 12 is connected to the pad 61b of the board 60 by, for example, a connecting member. The via 60Vb is provided between the pad 61b and the pad 62b. The via 60Vb electrically connects the pad 61b and the pad 62b. The pad 62b corresponds to the terminal 52 shown in the circuit diagram of FIG. 1. With this, the drain electrode 12d of the transistor 12 is electrically connected to the terminal 52 via the pad 61b and the via 60Vb.

As shown in FIGS. 3 and 6, the bonding wire 81 is provided between the source electrode 11s of the transistor 11 and the source electrode 12s of the transistor 12. One end of the bonding wire 81 is connected to the source electrode 11s of the transistor 11, and the other end of the bonding wire 81 is connected to the source electrode 12s of the transistor 12. With this, the bonding wire 81 electrically connects the source electrode 11s of the transistor 11 and the source electrode 12s of the transistor 12.

The structures of the transistor 13, the transistor 14, and the light receiver 20 are almost the same as the structures described above.

As shown in FIG. 4, the spacer 73g is provided between the gate electrode 13g of the transistor 13 and the electrode 20e of the light receiver 20. The spacer 73g is connected to the gate electrode 13g and the electrode 20e by, for example, a connecting member. With this, the electrode 20e of the light receiver 20 is electrically connected to the gate electrode 13g of the transistor 13 via the spacer 73g.

The spacer 73s is provided between the source electrode 13s of the transistor 13 and the electrode 20f of the light receiver 20. The spacer 73s is connected to the source electrode 13s and the electrode 20f by, for example, a connecting member. With this, the electrode 20f of the light receiver 20 is electrically connected to the source electrode 13s of the transistor 13 via the spacer 73s.

The drain electrode 13d of the transistor 13 is connected to the pad 61c of the board 60 by, for example, a connecting member. The via 60Vc is provided in the insulating layer 60a between the pad 61c and the pad 62c. The via 60Vc electrically connects the pad 61c and the pad 62c. The pad 62c corresponds to the terminal 53 shown in the circuit diagram of FIG. 1. With this, the drain electrode 13d of the transistor 13 is electrically connected to the terminal 53 via the pad 61c and the via 60Vc.

As shown in FIG. 5, the spacer 74g is provided between the gate electrode 14g of the transistor 14 and the electrode 20g of the light receiver 20. The spacer 74g is connected to the gate electrode 14g and the electrode 20g by, for example, a connecting member. With this, the electrode 20g of the light receiver 20 is electrically connected to the gate electrode 14g of the transistor 14 via the spacer 74g.

The spacer 74s is provided between the source electrode 14s of the transistor 14 and the electrode 20h of the light receiver 20. The spacer 74s is connected to the source electrode 14s and the electrode 20h by, for example, a connecting member. With this, the electrode 20h of the light receiver 20 is electrically connected to the source electrode 14s of the transistor 14 via the spacer 74s.

The drain electrode 14d of the transistor 14 is connected to the pad 61d of the board 60 by, for example, a connecting member. The via 60Vd is provided between the pad 61d and the pad 62d. The via 60Vd electrically connects the pad 61d and the pad 62d. The pad 62d corresponds to the terminal 54 shown in the circuit diagram of FIG. 1. With this, the drain electrode 14d of the transistor 14 is electrically connected to the terminal 54 via the pad 61d and the via 60Vd.

As shown in FIGS. 3 and 6, the bonding wire 82 is provided between the source electrode 13s of the transistor 13 and the source electrode 14s of the transistor 14. One end of the bonding wire 82 is connected to the source electrode 13s of the transistor 13, and the other end of the bonding wire 82 is connected to the source electrode 14s of the transistor 14. With this, the bonding wire 82 electrically connects the source electrode 13s of the transistor 13 and the source electrode 14s of the transistor 14.

The structures of the light emitter 30 and the board 60 are as described below.

As shown in FIGS. 3 and 4, the electrode 30a of the light emitter 30 is connected to the pad 61e of the board 60 by, for example, a connecting member. The via 60Ve is provided between the pad 61e and the pad 62e. The via 60Ve electrically connects the pad 61e and the pad 62e. The pad 62e corresponds to the terminal 41 shown in the circuit diagram of FIG. 1. With this, the electrode 30a of the light emitter 30 is electrically connected to the terminal 41 via the pad 61e and the via 60Ve.

As shown in FIG. 5, the electrode 30b of the light emitter 30 is connected to the pad 61f of the board 60 by, for example, a connecting member. The via 60Vf is provided between the pad 61f and the pad 62f. The via 60Vf electrically connects the pad 61f and the pad 62f. The pad 62f corresponds to the terminal 42 shown in the circuit diagram of FIG. 1. With this, the electrode 30b of the light emitter 30 is electrically connected to the terminal 42 via the pad 61f and the via 60Vf.

### 1.3. First Modification

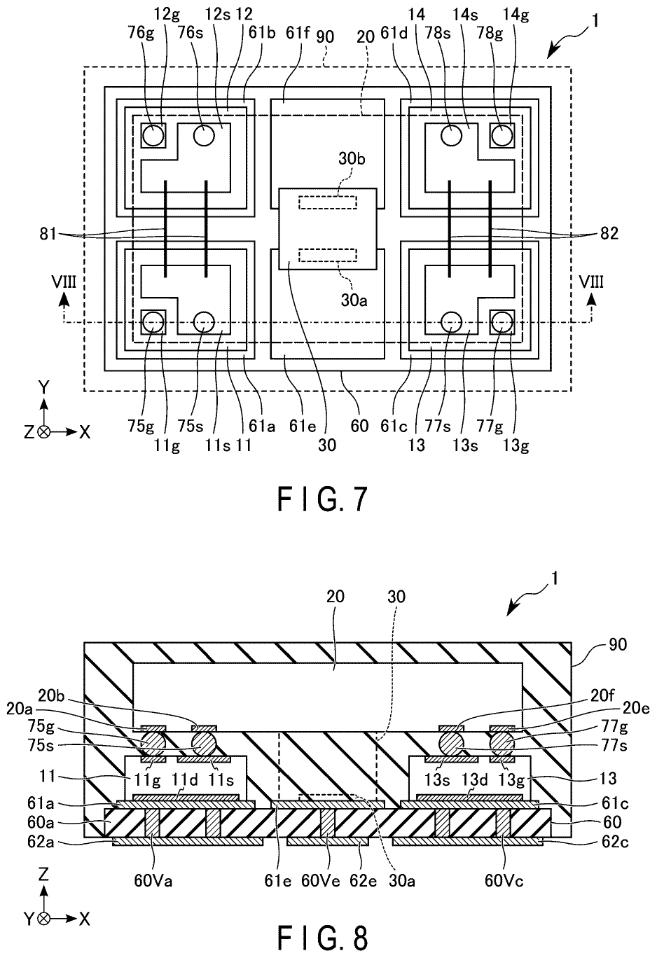

As the first modification of the first embodiment, a solder ball can be used in place of the spacer. FIG. 7 is a top view showing the structure of the photo relay device 1 according to the first modification of the first embodiment. FIG. 7 shows the structure of the photo relay device 1 when viewed through the resin member 90 and the light receiver 20 from the upper surface side in FIG. 2. FIG. 8 is a sectional view showing the structure of the photo relay device 1 according to the first modification of the first embodiment. FIG. 8 shows the sectional structure of the photo relay device 1 taken along a line VIII-VIII in FIG. 7.

In the first embodiment shown in FIG. 3, the spacers 71g, 71s, 72g, 72s, 73g, 73s, 74g, and 74s are used as the conductive members connecting the transistors 11, 12, 13, and 14 and the light receiver 20. In the first modification, as shown in FIGS. 7 and 8, solder balls 75g, 75s, 76g, 76s, 77g, 77s, 78g, and 78s are used in place of the spacers. Even by using the solder balls, the electrodes of the transistors 11, 12, 13, and 14 can be electrically connected to the electrodes of the light receiver 20. The remaining arrangement is similar to that of the first embodiment shown in FIG. 3.

### 1.4. Second Modification

Next, a semiconductor device according to the second modification of the first embodiment will be described. In the second modification, a photo relay device 1A supporting single communication will be described. The photo relay device 1A has a structure obtained by, for example, removing the transistors 13 and 14 and the members related to these transistors in FIG. 3.

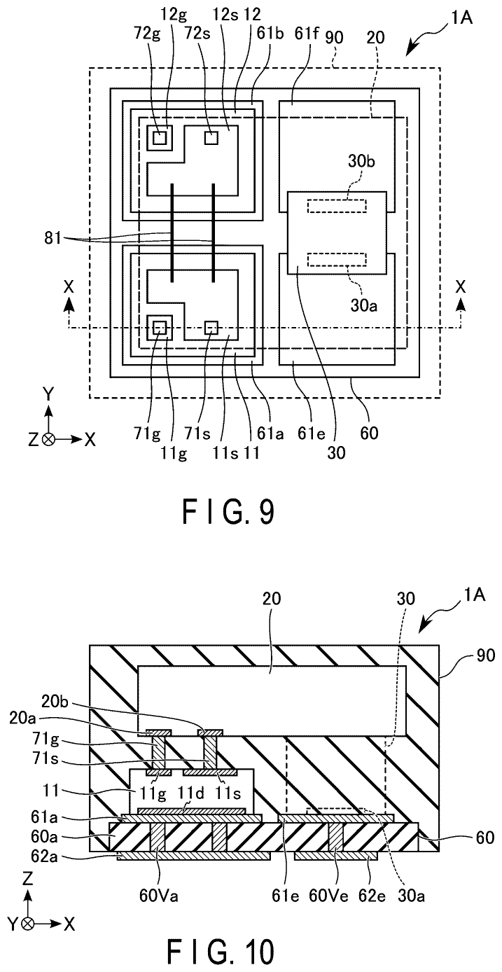

With reference to FIGS. 9 and 10, the structure of the photo relay device 1A according to the second modification of the first embodiment will be described. FIG. 9 is a top view showing the structure of the photo relay device 1A according to the second modification of the first embodiment. FIG. 9 shows the structure of the photo relay device 1A when viewed through the resin member 90 and the light receiver 20 from the upper surface side. FIG. 10 is a sectional view showing the structure of the photo relay device 1A according to the second modification of the first embodiment. FIG. 10 shows the sectional structure of the photo relay device 1A taken along a line X-X in FIG. 9.

As shown in FIGS. 9 and 10, the transistors 11 and 12 are provided on the board 60. The transistor 11 and the transistor 12 are arrayed in the Y direction.

The light emitter 30 is provided on the board 60. The light emitter 30 is arranged in the X direction with respect to the transistors 11 and 12.

The light receiver 20 is provided above the transistors 11 and 12 and the light emitter 30. When viewed from above, the light receiver 20 partially or entirely overlaps the transistors 11 and 12 and the light emitter 30. The light receiving surface of the light receiver 20 is arranged to face the light emitting surface of the light emitter 30.

The spacers 71g and 71s are provided between the transistor 11 and the light receiver 20. The spacers 72g and 72s are provided between the transistor 12 and the light receiver 20. The spacers 71g and 71s and the spacers 72g and 72s electrically connect the transistors 11 and 12 and the light receiver 20, respectively.

The bonding wire 81 is provided between the transistor 11 and the transistor 12. The bonding wire 81 electrically connects the transistor 11 and the transistor 12.

As shown in FIGS. 9 and 10, the remaining arrangement is similar to that in a structure obtained by removing the transistors 13 and 14 and the members related to these transistors from the structure shown in FIGS. 3, 4, 5, and 6.

Note that, in the second modification of the first embodiment as well, solder balls can be used in place of the spacers. Even by using the solder balls in place of the spacers, the electrodes of the transistors 11 and 12 can be electrically connected to the electrodes of the light receiver 20.

According to the first embodiment and modifications described above, a semiconductor device capable of miniaturization and performance improvement can be provided.

In general, in a photo relay device, bonding wires are used to connect a transistor, a light emitter, and a light receiver. Hence, pads for connecting the bonding wires and a height for arranging the bonding wires are necessary. This may make it difficult to miniaturize and reduce the thickness of the photo relay device. In addition, when the connection is made using the bonding wire, signal reflection between transistors and a connection problem between pads are likely to occur, which can result in a degradation in performance.

To prevent this, in the first embodiment and modifications, the light receiver 20 is arranged above (that is, in the Z direction) of the transistors and the light emitter 30, and the transistors are connected to the light receiver 20 by the spacers or solder balls. With this, the connections using the bonding wires, which hinder miniaturization and thickness reduction and cause performance degradation, are reduced as much as possible. This can achieve miniaturization, thickness reduction, and performance improvement of the photo relay device 1 or 1A.

In addition, by connecting the pad of the board 60 and the electrode of the light emitter 30 without using the bonding wire, further miniaturization, thickness reduction, and performance improvement can be achieved.

Note that, since the number of components and the number of connection points by the bonding wires are larger in the photo relay device 1 supporting differential communication than in the photo relay device 1A supporting single communication, miniaturization, thickness reduction, and performance improvement can be achieved more for the photo relay device 1 than for the photo relay device 1A.

That is, the photo relay device supporting single communication according to this embodiment has an effect of miniaturization and performance improvement. The photo relay device supporting differential communication has a greater effect of miniaturization than the photo relay device supporting single communication. Furthermore, the effect of miniaturization remarkably increases as the number of communication channels in the photo relay device increases.

### 2. Second Embodiment

A photo relay device 2 as a semiconductor device according to the second embodiment will be described. In the first embodiment, the bonding wire 81 (or 82) connects the transistor 11 (or 13) and the transistor 12 (or 14). In the second embodiment, the connection is made using not a bonding wire but a wiring provided in a light receiver 20. The remaining arrangement is similar to that in the first embodiment, and matters different from the first embodiment will be mainly described in the second embodiment.

### 2.1. Structure

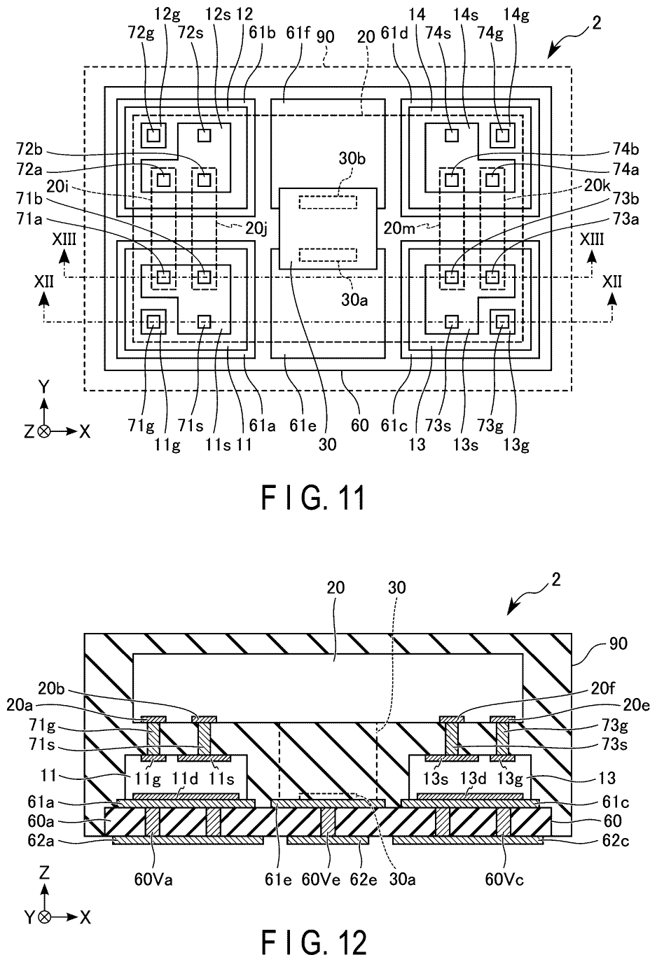

With reference to FIGS. 11, 12, and 13, the structure of the photo relay device 2 according to the second embodiment will be described.

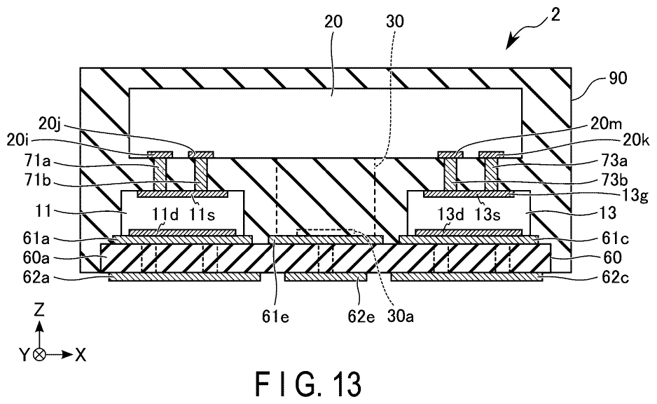

FIG. 11 is a top view showing the structure of the photo relay device 2 according to the second embodiment. FIG. 11 shows the structure of the photo relay device 2 when viewed through a resin member 90 and the light receiver 20 from the upper surface side. FIGS. 12 and 13 are sectional views showing the structure of the photo relay device 2 according to the second embodiment. FIG. 12 shows the sectional structure of the photo relay device 2 taken along a line XII-XII in FIG. 11. FIG. 13 shows the sectional structure of the photo relay device 2 taken along a line XIII-XIII in FIG. 11.

The photo relay device 2 includes spacers 71a, 71b, 72a, 72b, 73a, 73b, 74a, and 74b, in addition to transistors 11, 12, 13, and 14, the light receiver 20, a light emitter 30, a board 60, the resin member 90, and spacers 71g, 71s, 72g, 72s, 73g, 73s, 74g, and 74s. Furthermore, the light receiver 20 includes wirings (or electrodes or conductive layers) 20i, 20j, 20k, and 20m provided therein. For example, the wirings 20i, 20j, 20k, and 20m contain, for example, a conductive material such as copper.

The spacers 71a, 71b, 72a, 72b, 73a, 73b, 74a, and 74b, and the wirings 20i, 20j, 20k, and 20m in the light receiver 20 are provided in place of the bonding wires 81 and 82 in the arrangement according to the first embodiment.

The connection between a source electrode 11s of the transistor 11 and a source electrode 12s of the transistor 12 using the wirings 20i and 20j is as described below.

The spacer 71a is provided between the source electrode 11s of the transistor 11 and one end of the wiring (or electrode) 20i of the light receiver 20. The spacer 71a is connected to the source electrode 11s and one end of the wiring 20i by, for example, a connecting member (for example, a silver paste or a solder).

The spacer 72a is provided between the source electrode 12s of the transistor 12 and the other end of the wiring 20i of the light receiver 20. The spacer 72a is connected to the source electrode 12s and the other end of the wiring 20i by, for example, a connecting member.

With this, the source electrode 11s of the transistor 11 is electrically connected to the source electrode 12s of the transistor 12 via the spacer 71a, the wiring 20i, and the spacer 72a.

Similarly, the spacer 71b is provided between the source electrode 11s of the transistor 11 and one end of the wiring (or electrode) 20j of the light receiver 20. The spacer 71b is connected to the source electrode 11s and one end of the wiring 20j by, for example, a connecting member.

The spacer 72b is provided between the source electrode 12s of the transistor 12 and the other end of the wiring 20j of the light receiver 20. The spacer 72b is connected to the source electrode 12s and the other end of the wiring 20j by, for example, a connecting member.

With this, the source electrode 11s of the transistor 11 is electrically connected to the source electrode 12s of the transistor 12 via the spacer 71b, the wiring 20j, and the spacer 72b.

The connection between a source electrode 13s of the transistor 13 and a source electrode 14s of the transistor 14 using the wirings 20k and 20m is as described below.

The spacer 73a is provided between the source electrode 13s of the transistor 13 and one end of the wiring (or electrode) 20k of the light receiver 20. The spacer 73a is connected to the source electrode 13s and one end of the wiring 20k by, for example, a connecting member.

The spacer 74a is provided between the source electrode 14s of the transistor 14 and the other end of the wiring 20k of the light receiver 20. The spacer 74a is connected to the source electrode 14s and the other end of the wiring 20k by, for example, a connecting member.

With this, the source electrode 13s of the transistor 13 is electrically connected to the source electrode 14s of the transistor 14 via the spacer 73a, the wiring 20k, and the spacer 74a.

Similarly, the spacer 73b is provided between the source electrode 13s of the transistor 13 and one end of the wiring (or electrode) 20m of the light receiver 20. The spacer 73b is connected to the source electrode 13s and one end of the wiring 20m by, for example, a connecting member.

The spacer 74b is provided between the source electrode 14s of the transistor 14 and the other end of the wiring 20m of the light receiver 20. The spacer 74b is connected to the source electrode 14s and the other end of the wiring 20m by, for example, a connecting member.

With this, the source electrode 13s of the transistor 13 is electrically connected to the source electrode 14s of the transistor 14 via the spacer 73b, the wiring 20m, and the spacer 74b.

The remaining arrangement is similar to that of the first embodiment shown in FIG. 3.

### 2.2. First Modification

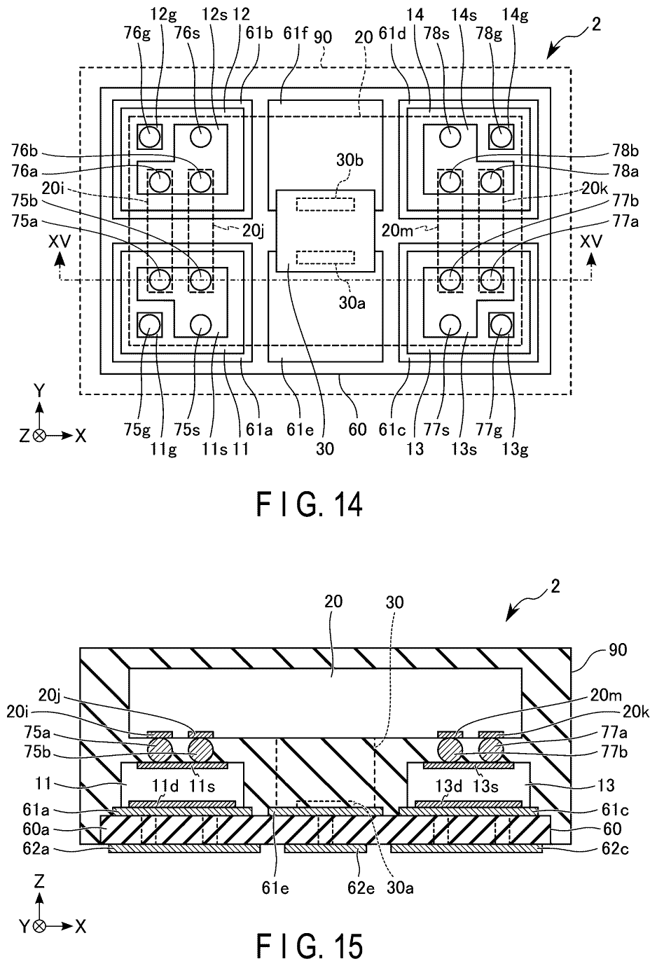

As the first modification of the second embodiment, a solder ball can be used in place of the spacer. FIG. 14 is a top view showing the structure of the photo relay device 2 according to the first modification of the second embodiment. FIG. 14 shows the structure of the photo relay device 2 when viewed through the resin member 90 and the light receiver 20 from the upper surface side. FIG. 15 is a sectional view showing the structure of the photo relay device 2 according to the first modification of the second embodiment. FIG. 15 shows the sectional structure of the photo relay device 2 taken along a line XV-XV in FIG. 14.

In the second embodiment shown in FIG. 11, the spacers 71g, 71s, 72g, 72s, 73g, 73s, 74g, and 74s, and the spacers 71a, 71b, 72a, 72b, 73a, 73b, 74a, and 74b are used as the conductive members connecting the transistors 11, 12, 13, and 14 and the light receiver 20. However, in the first modification, as shown in FIGS. 14 and 15, solder balls 75g, 75s, 76g, 76s, 77g, 77s, 78g, and 78s, and solder balls 75a, 75b, 76a, 76b, 77a, 77b, 78a, and 78b are used in place of the spacers.

Even by using the solder balls in place of the spacers, the electrodes of the transistors 11, 12, 13, and 14 can be electrically connected to the electrodes of the light receiver 20. The remaining arrangement is similar to that of the second embodiment shown in FIG. 11.

### 2.3. Second Modification

Next, a semiconductor device according to the second modification of the second embodiment will be described. In the second modification, a photo relay device 2A supporting single communication will be described. The photo relay device 2A has a structure obtained by, for example, removing the transistors 13 and 14 and the members related to these transistors in FIG. 11.

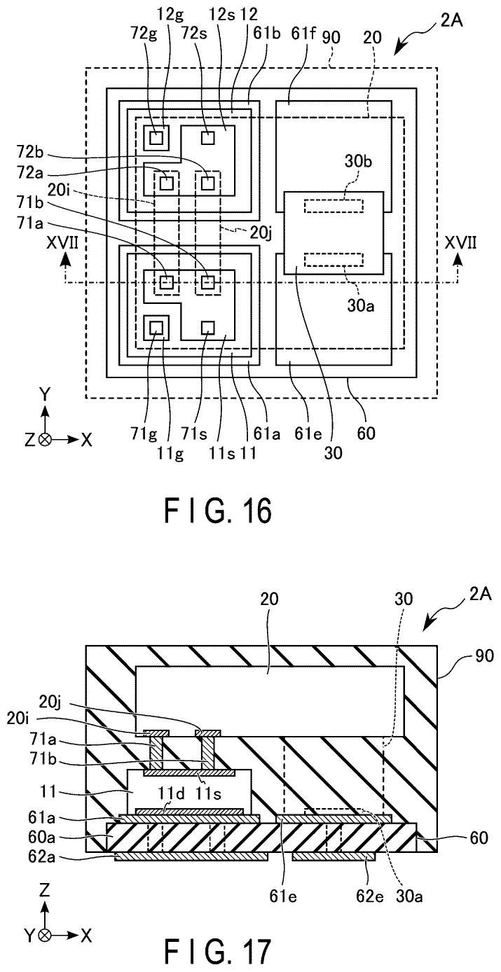

With reference to FIGS. 16 and 17, the structure of the photo relay device 2A according to the second modification of the second embodiment will be described. FIG. 16 is a top view showing the structure of the photo relay device 2A according to the second modification of the second embodiment. FIG. 16 shows the structure of the photo relay device 2A when viewed through the resin member 90 and the light receiver 20 from the upper surface side. FIG. 17 is a sectional view showing the structure of the photo relay device 2A according to the second modification of the second embodiment. FIG. 17 shows the sectional structure of the photo relay device 2A taken along a line XVII-XVII in FIG. 16.

As shown in FIGS. 16 and 17, the transistors 11 and 12 are provided on the board 60. The transistor 11 and the transistor 12 are arrayed in the Y direction.

The light emitter 30 is provided on the board 60. The light emitter 30 is arranged in the X direction with respect to the transistors 11 and 12.

The light receiver 20 is provided above the transistors 11 and 12 and the light emitter 30. When viewed from above, the light receiver 20 partially or entirely overlaps the transistors 11 and 12 and the light emitter 30. The light receiving surface of the light receiver 20 is arranged to face the light emitting surface of the light emitter 30.

The spacers 71g and 71s are provided between the transistor 11 and the light receiver 20. The spacers 72g and 72s are provided between the transistor 12 and the light receiver 20. The spacers 71g and 71s and the spacers 72g and 72s electrically connect the transistors 11 and 12 and the light receiver 20, respectively.

The spacers 71a and 71b, the wirings 20i and 20j in the light receiver 20, and the spacers 72a and 72b are provided between the transistor 11 and the transistor 12. The transistor 11 is electrically connected to the transistor 12 via the spacer 71a, the wiring 20i in the light receiver 20, and the spacer 72a. Similarly, the transistor 11 is electrically connected to the transistor 12 via the spacer 71b, the wiring 20j in the light receiver 20, and the spacer 72b.

As shown in FIGS. 16 and 17, the remaining arrangement is similar to that in a structure obtained by removing the transistors 13 and 14 and the members related to these transistors from the structure shown in FIGS. 11, 12, and 13.

Note that, in the second modification of the second embodiment as well, solder balls can be used in place of the spacers. Even by using the solder balls in place of the spacers, the electrodes of the transistors 11 and 12 can be electrically connected to the electrodes of the light receiver 20.

According to the second embodiment and modifications described above, a semiconductor device capable of miniaturization and performance improvement can be provided.

In the second embodiment and modifications, the light receiver 20 is arranged above (that is, in the Z direction) the transistors and the light emitter 30. Furthermore, the transistors are connected to the light receiver 20 by the spacers or solder balls, and the transistors are connected to each other by the spacers and the wirings provided in the light receiver 20. With this, the connection by the bonding wire, which hinders miniaturization and thickness reduction and causes performance degradation, is eliminated. This can achieve miniaturization, thickness reduction, and performance improvement of the photo relay device 2 or 2A.

In addition, by connecting the pad of the board 60 and the electrode of the light emitter 30 without using the bonding wire, further miniaturization, thickness reduction, and performance improvement can be achieved.

Furthermore, in the second embodiment and modifications, the transistor 11 (or 13) and the transistor 12 (or 14) are connected using the wiring provided in the light receiver 20. Hence, by adjusting the width and (or) thickness of the wiring, it is possible to connect the transistors 11 and 12 with lower loss than in a case where they are connected using the bonding wire. This can improve the performance of the photo relay device.

Note that, as in the first embodiment, since the number of components and the number of connection points by the bonding wires are larger in the photo relay device 2 supporting differential communication than in the photo relay device 2A supporting single communication, miniaturization, thickness reduction, and performance improvement can be achieved more for the photo relay device 2 than for the photo relay device 2A.

That is, the photo relay device supporting single communication according to this embodiment has an effect of miniaturization and performance improvement. The photo relay device supporting differential communication has a greater effect of miniaturization than the photo relay device supporting single communication. Furthermore, the effect of miniaturization remarkably increases as the number of communication channels in the photo relay device increases.

### 3. Third Embodiment

A photo relay device 3 as a semiconductor device according to the third embodiment will be described. In the first and second embodiments, the transistors 11, 12, 13, and 14 are provided on the board 60. In the third embodiment, transistors 11, 12, 13, and 14 are provided in a board. Matters different from the first embodiment will be mainly described in the third embodiment.

### 3.1. Structure

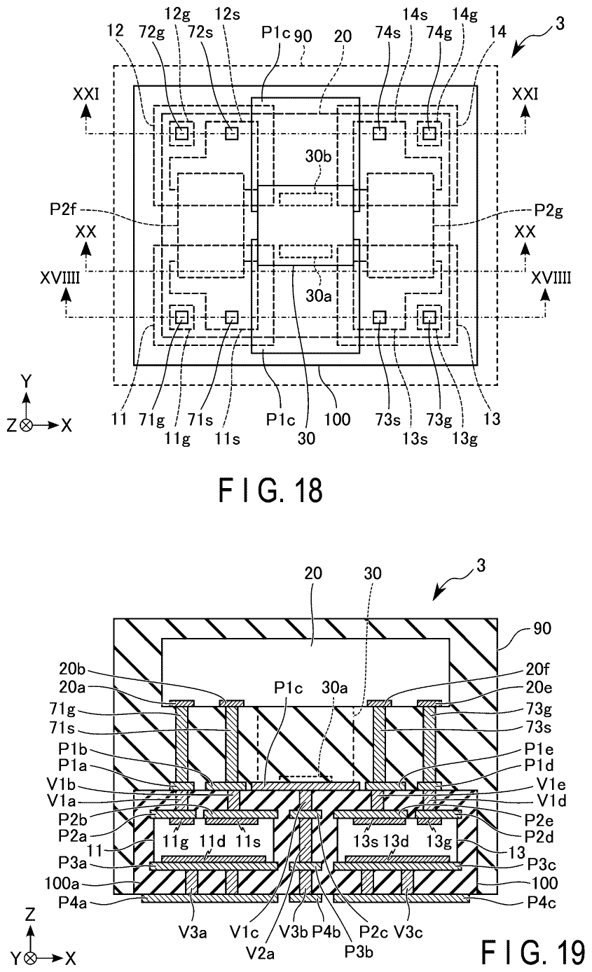

With reference to FIGS. 18, 19, 20, and 21, the structure of the photo relay device 3 according to the third embodiment will be described.

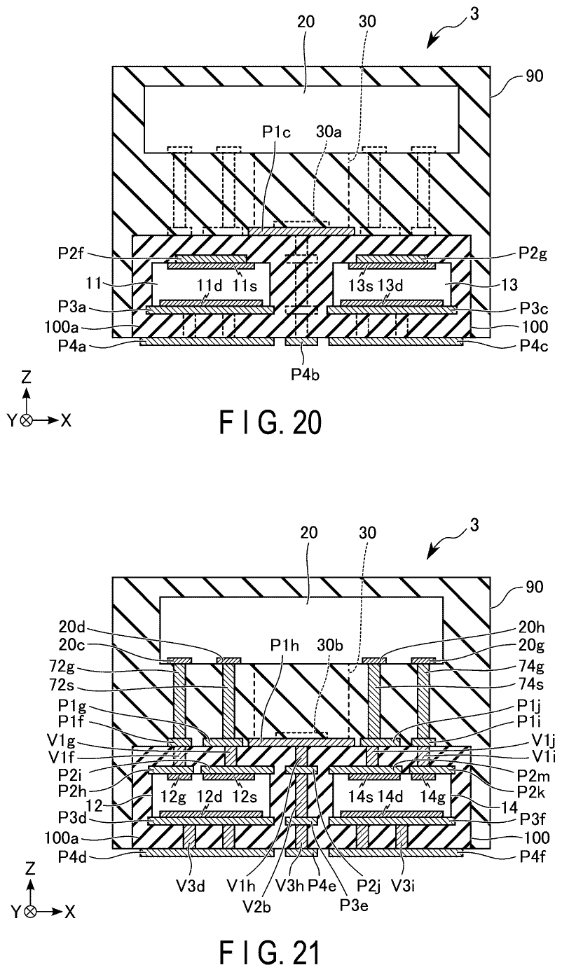

FIG. 18 is a top view showing the structure of the photo relay device 3 according to the third embodiment. FIG. 18 shows the structure of the photo relay device 3 when viewed through a resin member 90, a light receiver 20, an insulating layer 100a of a board 100, pads, and vias from the upper surface side. FIGS. 19, 20, and 21 are sectional views showing the structure of the photo relay device 3 according to the third embodiment. FIG. 19 shows the sectional structure of the photo relay device 3 taken along a line XVIIII-XVIIII in FIG. 18. FIG. 20 shows the sectional structure of the photo relay device 3 taken along a line XX-XX in FIG. 18. FIG. 21 shows the sectional structure of the photo relay device 3 taken along a line XXI-XXI in FIG. 18.

The photo relay device 3 includes the transistors 11, 12, 13, and 14, the light receiver 20, a light emitter 30, the board 100, the resin member 90, and spacers 71g, 71s, 72g, 72s, 73g, 73s, 74g, and 74s.

The board 100 is, for example, a multilayered wiring board including multiple layers of wirings and pads. The board 100 includes the insulating layer 100a, a plurality of pads (and/or wirings or conductive layers) P1, P2, P3, and P4, and a plurality of vias V1, V2, and V3.

The pads P1 include pads P1a, P1b, P1c, P1d, P1e, P1f, P1g, P1h, P1i, and P1j. The pads P2 include pads P2a, P2b, P2c, P2d, P2e, P2f, P2g, P2h, P2i, P2j, P2k, and P2m. The pads P3 include pads P3a, P3b, P3c, P3d, P3e, and P3f. The pads P4 include pads P4a, P4b, P4c, P4d, P4e, and P4f.

The vias V1 include vias V1a, V1b, V1c, V1d, V1e, V1f, V1g, V1h, V1i, and V1j. The vias V2 include vias V2a and V2b. The vias V3 include vias V3a, V3b, V3c, V3d, V3e, and V3f, V3g, V3h, and V3i.

The pads P1 are provided on the first surface (or upper surface) of the board 100 (or the insulating layer 100a). The pads P2 and P3 are provided in the board 100 (or the insulating layer 100a). The pads P4 are provided on the second surface (or lower surface) of the board 100 (or the insulating layer 100a). The second surface is a surface facing the first surface, or a surface on the opposite side of the first surface. The pads P1, P2, P3, and P4 contain, for example, a conductive material such as copper.

The vias V1, V2, and V3 are provided in the board 100 (or the insulating layer 100a). The via V1 is provided to extend through the insulating layer 100a between the pad P1 on the first surface and the pad P2, and electrically connects the pad P1 and the pad P2. The via V2 is provided to extend through the insulating layer 100a between the pad P2 and the pad P3, and electrically connects the pad P2 and the pad P3. The via V3 is provided to extend through the insulating layer 100a between the pad P3 and the pad P4 on the second surface, and electrically connects the pad P3 and the pad P4. The vias V1, V2, and V3 contain, for example, a conductive material such as copper.

The transistors 11, 12, 13, and 14 are provided in the board 100 (or the insulating layer 100a). The transistors 11 and 12 and the transistors 13 and 14 are arranged closer to each other in the X direction than in the first embodiment. That is, the distance between the transistors 11 and 12 and the transistors 13 and 14 is shorter than in the first embodiment.

The structures of the transistor 11, the transistor 12, and the light receiver 20 are as described below.

As described above, the transistors 11 and 12 are arrayed in the Y direction in the board 100.

As shown in FIG. 19, the pad P2a is provided on a gate electrode 11g of the transistor 11. The gate electrode 11g of the transistor 11 is connected to the pad P2a by, for example, a connecting member (for example, a silver paste or a solder). The via V1a is provided on the pad P2a, and the pad P1a is provided on the via V1a. The pad P1a is the pad provided on the first surface of the board 100. With this, the gate electrode 11g of the transistor 11 is electrically connected to the pad P1a via the pad P2a and the via V1a.

The spacer 71g is provided between the pad P1a and an electrode 20a of the light receiver 20. The lower end of the spacer 71g is connected to the pad P1a by, for example, a connecting member (for example, a silver paste or a solder). The upper end of the spacer 71g is connected to the electrode 20a by, for example, a connecting member. The electrode 20a is electrically connected to the pad P1a via the spacer 71g. With this, the electrode 20a of the light receiver 20 is electrically connected to the gate electrode 11g of the transistor 11 via the spacer 71g, the pad P1a, the via V1a, and the pad P2a.

The pad P2b is provided on a source electrode 11s of the transistor 11. The source electrode 11s of the transistor 11 is connected to the pad P2b by, for example, a connecting member. The via V1b is provided on the pad P2b, and the pad P1b is provided on the via V1b. The pad P1b is the pad provided on the first surface of the board 100. With this, the source electrode 11s of the transistor 11 is electrically connected to the pad P1b via the pad P2b and the via V1b.

The spacer 71s is provided between the pad P1b and an electrode 20b of the light receiver 20. The lower end of the spacer 71s is connected to the pad P1b by, for example, a connecting member. The upper end of the spacer 71s is connected to the electrode 20b by, for example, a connecting member. The electrode 20b is electrically connected to the pad P1b via the spacer 71s. With this, the electrode 20b of the light receiver 20 is electrically connected to the source electrode 11s of the transistor 11 via the spacer 71s, the pad P1b, the via V1b, and the pad P2b.

The pad P3a is provided under a drain electrode 11d of the transistor 11. The drain electrode 11d of the transistor 11 is connected to the pad P3a by, for example, a connecting member. The via V3a is provided under the pad P3a, and the pad P4a is provided under the via V3a. The pad P4a is the pad provided on the second surface of the board 100. With this, the drain electrode 11d of the transistor 11 is electrically connected to the pad P4a via the pad P3a and the via V3a. The pad P4a corresponds to a terminal 51 shown in the circuit diagram of FIG. 1.

As shown in FIGS. 18 and 20, the pad/wiring (or interconnect, conductive layer) P2f is provided in the board 100 (or the insulating layer 100a). The pad/wiring P2f is provided on the source electrodes of the transistors 11 and 12 to be placed across the source electrode 11s of the transistor 11 and a source electrode 12s of the transistor 12. That is, one end of the pad/wiring P2f is arranged on one end of the source electrode 11s of the transistor 11, and the other end of the pad/wiring P2f is arranged on one end of the source electrode 12s of the transistor 12.

One end of the source electrode 11s of the transistor 11 is connected to one end of the pad/wiring P2f by, for example, a connecting member (for example, a silver paste or a solder). Similarly, one end of the source electrode 12s of the transistor 12 is connected to the other end of the pad/wiring P2f by a connecting member. With this, the source electrode 11s of the transistor 11 is electrically connected to the source electrode 12s of the transistor 12 via the pad/wiring P2f.

In addition, as shown in FIG. 21, the pad P2h is provided on a gate electrode 12g of the transistor 12. The gate electrode 12g of the transistor 12 is connected to the pad P2h by, for example, a connecting member (for example, a silver paste or a solder). The via V1f is provided on the pad P2h, and the pad P1f is provided on the via V1f. The pad P1f is the pad provided on the first surface of the board 100. With this, the gate electrode 12g of the transistor 12 is electrically connected to the pad P1f via the pad P2h and the via V1f.

The spacer 72g is provided between the pad P1f and an electrode 20c of the light receiver 20. The lower end of the spacer 72g is connected to the pad P1f by, for example, a connecting member (for example, a silver paste or a solder). The upper end of the spacer 72g is connected to the electrode 20c by, for example, a connecting member. The electrode 20c is electrically connected to the pad P1f via the spacer 72g. With this, the electrode 20c of the light receiver 20 is electrically connected to the gate electrode 12g of the transistor 12 via the spacer 72g, the pad P1f, the via V1f, and the pad P2h.

The pad P2i is provided on the source electrode 12s of the transistor 12. The source electrode 12s of the transistor 12 is connected to the pad P2i by, for example, a connecting member. The via V1g is provided on the pad P2i, and the pad P1g is provided on the via V1g. The pad P1g is the pad provided on the first surface of the board 100. With this, the source electrode 12s of the transistor 12 is electrically connected to the pad P1g via the pad P2i and the via V1g.

The spacer 72s is provided between the pad P1g and an electrode 20d of the light receiver 20. The lower end of the spacer 72s is connected to the pad P1g by, for example, a connecting member. The upper end of the spacer 72s is connected to the electrode 20d by, for example, a connecting member. The electrode 20d is electrically connected to the pad P1g via the spacer 72s. With this, the electrode 20d of the light receiver 20 is electrically connected to the source electrode 12s of the transistor 12 via the spacer 72s, the pad P1g, the via V1g, and the pad P2i.

The pad P3d is provided under a drain electrode 12d of the transistor 12. The drain electrode 12d of the transistor 12 is connected to the pad P3d by, for example, a connecting member. The via V3d is provided under the pad P3d, and the pad P4d is provided under the via V3d. The pad P4d is the pad provided on the second surface of the board 100. With this, the drain electrode 12d of the transistor 12 is electrically connected to the pad P4d via the pad P3d and the via V3d. The pad P4d corresponds to a terminal 52 shown in the circuit diagram of FIG. 1.

The above description applies to the structures of the transistor 13, the transistor 14, and the light receiver 20.

As described above, the transistors 13 and 14 are arrayed in the Y direction in the board 100.

As shown in FIG. 19, the pad P2d is provided on a gate electrode 13g of the transistor 13. The gate electrode 13g of the transistor 13 is connected to the pad P2d by, for example, a connecting member (for example, a silver paste or a solder). The via V1d is provided on the pad P2d, and the pad P1d is provided on the via V1d. The pad P1d is the pad provided on the first surface of the board 100. With this, the gate electrode 13g of the transistor 13 is electrically connected to the pad P1d via the pad P2d and the via V1d.

The spacer 73g is provided between the pad P1d and an electrode 20e of the light receiver 20. The spacer 73g is connected to the pad P1d and the electrode 20e by, for example, a connecting member. The electrode 20e is electrically connected to the pad P1d via the spacer 73g. With this, the electrode 20e of the light receiver 20 is electrically connected to the gate electrode 13g of the transistor 13 via the spacer 73g, the pad P1d, the via V1d, and the pad P2d.

The pad P2e is provided on a source electrode 13s of the transistor 13. The source electrode 13s of the transistor 13 is connected to the pad P2e by, for example, a connecting member. The via V1e is provided on the pad P2e, and the pad P1e is provided on the via V1e. The pad P1e is the pad provided on the first surface of the board 100. With this, the source electrode 13s of the transistor 13 is electrically connected to the pad P1e via the pad P2e and the via V1e.

The spacer 73s is provided between the pad P1e and an electrode 20f of the light receiver 20. The spacer 73s is connected to the pad P1e and the electrode 20f by, for example, a connecting member. The electrode 20f is electrically connected to the pad P1e via the spacer 73s. With this, the electrode 20f of the light receiver 20 is electrically connected to the source electrode 13s of the transistor 13 via the spacer 73s, the pad P1e, the via V1e, and the pad P2e.

The pad P3c is provided under a drain electrode 13d of the transistor 13. The drain electrode 13d of the transistor 13 is connected to the pad P3c by, for example, a connecting member. The via V3c is provided under the pad P3c, and the pad P4c is provided under the via V3c. The pad P4c is the pad provided on the second surface of the board 100. With this, the drain electrode 13d of the transistor 13 is electrically connected to the pad P4c via the pad P3c and the via V3c. The pad P4c corresponds to a terminal 53 shown in the circuit diagram of FIG. 1.

As shown in FIGS. 18 and 20, the pad/wiring P2g is provided in the board 100 (or the insulating layer 100a). The pad/wiring P2g is provided on the source electrodes of the transistors 13 and 14 to be placed across the source electrode 13s of the transistor 13 and a source electrode 14s of the transistor 14. That is, one end of the pad/wiring P2g is arranged on one end of the source electrode 13s of the transistor 13, and the other end of the pad/wiring P2g is arranged on one end of the source electrode 14s of the transistor 14.

One end of the source electrode 13s of the transistor 13 is connected to one end of the pad/wiring P2g by, for example, a connecting member (for example, a silver paste or a solder). Similarly, one end of the source electrode 14s of the transistor 14 is connected to the other end of the pad/wiring P2g by a connecting member. With this, the source electrode 13s of the transistor 13 is electrically connected to the source electrode 14s of the transistor 14 via the pad/wiring P2g.

In addition, as shown in FIG. 21, the pad P2k is provided on a gate electrode 14g of the transistor 14. The gate electrode 14g of the transistor 14 is connected to the pad P2k by, for example, a connecting member (for example, a silver paste or a solder). The via V1i is provided on the pad P2k, and the pad P1i is provided on the via V1i. The pad P1i is the pad provided on the first surface of the board 100. With this, the gate electrode 14g of the transistor 14 is electrically connected to the pad P1i via the pad P2k and the via V1i.

The spacer 74g is provided between the pad P1i and an electrode 20g of the light receiver 20. The lower end of the spacer 74g is connected to the pad P1i by, for example, a connecting member (for example, a silver paste or a solder). The upper end of the spacer 74g is connected to the electrode 20g by, for example, a connecting member. The electrode 20g is electrically connected to the pad P1i via the spacer 74g. With this, the electrode 20g of the light receiver 20 is electrically connected to the gate electrode 14g of the transistor 14 via the spacer 74g, the pad P1i, the via V1i, and the pad P2k.

The pad P2m is provided on the source electrode 14s of the transistor 14. The source electrode 14s of the transistor 14 is connected to the pad P2m by, for example, a connecting member. The via V1j is provided on the pad P2m, and the pad P1j is provided on the via V1j. The pad P1j is the pad provided on the first surface of the board 100. With this, the source electrode 14s of the transistor 14 is electrically connected to the pad P1j via the pad P2m and the via V1j.

The spacer 74s is provided between the pad P1j and an electrode 20h of the light receiver 20. The lower end of the spacer 74s is connected to the pad P1j by, for example, a connecting member. The upper end of the spacer 74s is connected to the electrode 20h by, for example, a connecting member. The electrode 20h is electrically connected to the pad P1j via the spacer 74s. With this, the electrode 20h of the light receiver 20 is electrically connected to the source electrode 14s of the transistor 14 via the spacer 74s, the pad P1j, the via V1j, and the pad P2m.

The pad P3f is provided under a drain electrode 14d of the transistor 14. The drain electrode 14d of the transistor 14 is connected to the pad P3f by, for example, a connecting member. The via V3i is provided under the pad P3f, and the pad P4f is provided under the via V3i. The pad P4f is the pad provided on the second surface of the board 100. With this, the drain electrode 14d of the transistor 14 is electrically connected to the pad P4f via the pad P3f and the via V3i. The pad P4f corresponds to a terminal 54 shown in the circuit diagram of FIG. 1. The spacers 71g, 71s, 72g, 72s, 73g, 73s, 74g and 74s are approximately equal in length in the Z direction.

As shown in FIG. 18, the light emitter 30 is provided on the board 100. The light emitter 30 is arranged above the vicinity of the center between the transistors 11 and 12 and the transistors 13 and 14 in the X direction. The light emitter 30 includes a light emitting surface in its upper surface.

The light receiver 20 is provided above (that is, in the Z direction) the board 100 and the light emitter 30. When viewed from above, the light receiver 20 partially or entirely overlaps the transistors 11, 12, 13, and 14 and the light emitter 30. The light receiver 20 includes a light receiving surface in its lower surface. The light receiving surface of the light receiver 20 is arranged to face the light emitting surface of the light emitter 30.

Note that, in the third embodiment as well, a solder ball can be used in place of the spacer. Even by using the solder balls in place of the spacers, the electrodes of the transistors 11, 12, 13, and 14 can be electrically connected to the electrodes of the light receiver 20.

### 3.2. Modification

Next, a semiconductor device according to a modification of the third embodiment will be described. In the modification, a photo relay device 3A supporting single communication will be described. The photo relay device 3A has a structure obtained by, for example, removing the transistors 13 and 14 and the members related to these transistors in FIG. 18.

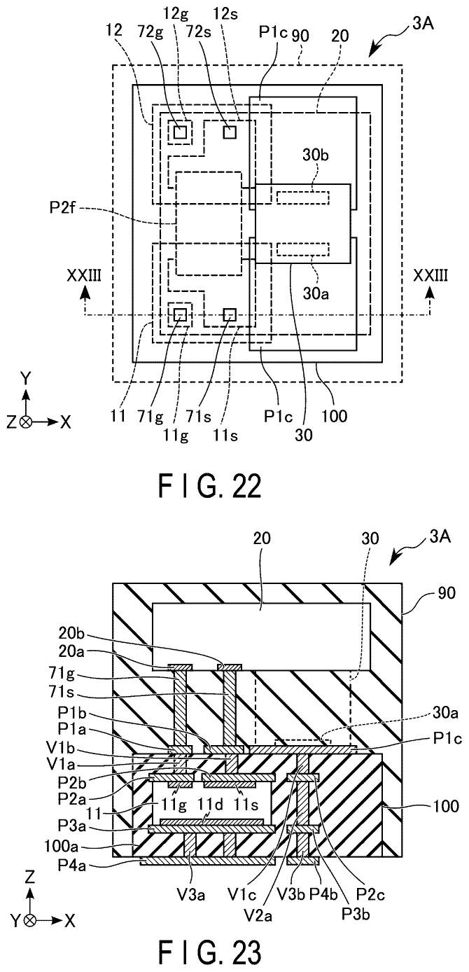

With reference to FIGS. 22 and 23, the structure of the photo relay device 3A according to the modification of the third embodiment will be described. FIG. 22 is a top view showing the structure of the photo relay device 3A according to the modification of the third embodiment. FIG. 22 shows the structure of the photo relay device 3A when viewed through the resin member 90, the light receiver 20, the insulating layer 100a of the board 100, pads, and vias from the upper surface side. FIG. 23 is a sectional view showing the structure of the photo relay device 3A according to the modification of the third embodiment. FIG. 23 shows the sectional structure of the photo relay device 3A taken along a line XXIII-XXIII in FIG. 22.

As shown in FIGS. 22 and 23, the transistors 11 and 12 are provided in the board 100. The transistor 11 and the transistor 12 are arrayed in the Y direction.

The pad/wiring P2f is provided in the board 100. The pad/wiring P2f is arranged on the source electrode 11s of the transistor 11 and the source electrode 12s of the transistor 12. One end of the pad/wiring P2f is connected to the source electrode 11s of the transistor 11. The other end of the pad/wiring P2f is connected to the source electrode 12s of the transistor 12. With this, the source electrode 11s of the transistor 11 is electrically connected to the source electrode 12s of the transistor 12 via the pad/wiring P2f.

The light emitter 30 is provided on the board 100. The light emitter 30 is arranged in the X direction with respect to the transistors 11 and 12.

The light receiver 20 is provided above the board 100 and the light emitter 30. When viewed from above, the light receiver 20 partially or entirely overlaps the transistors 11 and 12 and the light emitter 30. The light receiving surface of the light receiver 20 is arranged to face the light emitting surface of the light emitter 30.

As shown in FIGS. 22 and 23, the remaining arrangement is similar to that in a structure obtained by removing the transistors 13 and 14 and the members related to these transistors from the structure shown in FIGS. 18, 19, 20, and 21.

Note that, in the modification of the third embodiment as well, a solder ball can be used in place of the spacer. Even by using the solder balls in place of the spacers, the electrodes of the transistors 11 and 12 can be electrically connected to the electrodes of the light receiver 20.

According to the third embodiment and modification described above, a semiconductor device capable of miniaturization and performance improvement can be provided.

In the third embodiment and modification, the transistors are arranged in the board 100, and the light receiver 20 is arranged above (that is, in the Z direction) the board 100 and the light emitter 30. Furthermore, the pads on the board 100 connected to the transistors are connected to the light receiver 20 by the spacers, and the transistors are connected to each other by the wirings provided in the board 100. With this, the connection by the bonding wire, which hinders miniaturization and thickness reduction and causes performance degradation, is eliminated. This can achieve miniaturization, thickness reduction, and performance improvement of the photo relay device 3 or 3A.

In addition, since the transistors 11, 12, 13, and 14 are arranged in the board 100, there is no need to ensure a region for arranging the light emitter 30, and the transistors 11 and 12 can be brought closer to the transistors 13 to 14. This can achieve further miniaturization, thickness reduction, and performance improvement of the photo relay device 3 or 3A.

Furthermore, in the third embodiment and modification, the transistor 11 (or 13) and the transistor 12 (or 14) are connected using the wiring provided in the board 100. Hence, by adjusting the width and (or) thickness of the wiring, it is possible to connect the transistors 11 and 12 with lower loss than in a case where they are connected using the bonding wire. This can improve the performance of the photo relay device.

In addition, by connecting the pad of the board 100 and the electrode of the light emitter 30 without using the bonding wire, further miniaturization, thickness reduction, and performance improvement can be achieved.

Note that, as in the first embodiment, since the number of components and the number of connection points by the bonding wires are larger in the photo relay device 3 supporting differential communication than in the photo relay device 3A supporting single communication, miniaturization, thickness reduction, and performance improvement can be achieved more for the photo relay device 3 than for the photo relay device 3A.

That is, the photo relay device supporting single communication according to this embodiment has an effect of miniaturization and performance improvement. The photo relay device supporting differential communication has a greater effect of miniaturization than the photo relay device supporting single communication. Furthermore, the effect of miniaturization remarkably increases as the number of communication channels in the photo relay device increases.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor provided above a first surface of a board;
a second transistor provided above the first surface of the board, and arranged in a first direction along the first surface of the board with respect to the first transistor;
a light emitter provided above the first surface of the board, and arranged in a second direction perpendicular to the first direction and along the first surface of the board with respect to the first transistor and the second transistor;
a light receiver provided above the first transistor, the second transistor, and the light emitter;
a first spacer provided between the first transistor and the light receiver, and electrically connecting the first transistor and the light receiver; and
a second spacer provided between the second transistor and the light receiver, and electrically connecting the second transistor and the light receiver.

2. The semiconductor device according to claim 1, further comprising
a bonding wire provided above the first transistor and the second transistor and below the light receiver, and electrically connecting the first transistor and the second transistor.

3. The semiconductor device according to claim 1, further comprising:
a third spacer provided between the first transistor and the light receiver;
a fourth spacer provided between the second transistor and the light receiver; and
a conductive layer provided in the light receiver, and arranged between the third spacer and the fourth spacer.

4. The semiconductor device according to claim 1, wherein
the first transistor has a first chip shape,
the second transistor has a second chip shape,
the light emitter has a third chip shape,
the light receiver has a fourth chip shape, and
when viewed from above, the fourth chip shape overlaps the first chip shape, the second chip shape, and the third chip shape.

5. The semiconductor device according to claim 1, further comprising:
a third transistor provided above the first surface of the board; and
a fourth transistor provided above the first surface of the board, and arranged in the first direction with respect to the third transistor.

6. The semiconductor device according to claim 5, wherein
the first transistor and the third transistor are arranged in line symmetry with respect to a line along the first direction, and
the second transistor and the fourth transistor are arranged in line symmetry with respect to a line along the first direction.

7. The semiconductor device according to claim 1, wherein
assuming that a direction above the first surface of the board is a third direction,
in the third direction, a length of the first spacer is equal to a length of the second spacer.

8. The semiconductor device according to claim 1, wherein
the light emitter includes a light emitting surface,
the light receiver includes a light receiving surface, and
the light receiving surface of the light receiver is arranged to face the light emitting surface of the light emitter.

9. The semiconductor device according to claim 1, wherein
the first spacer and the second space contain at least one of copper and an alloy.

10. The semiconductor device according to claim 5, wherein
a first signal is transmitted via the first transistor and the second transistor, and
a second signal, which is an inverted signal of the first signal, is transmitted via the third transistor and the fourth transistor.

11. A semiconductor device comprising:
a first transistor provided in a board;
a second transistor provided in the board, and arranged in a first direction along the first surface of the board with respect to the first transistor;
a light emitter provided above the first transistor and the second transistor and above the first surface of the board;
a light receiver provided above the board and the light emitter;
a first spacer provided between the board and the light receiver, and electrically connecting the first transistor and the light receiver; and
a second spacer provided between the board and the light receiver, and electrically connecting the second transistor and the light receiver.

12. The semiconductor device according to claim 11, further comprising
a conductive layer provided in the board,
wherein the conductive layer is arranged between the first transistor and the second transistor, and electrically connects the first transistor and the second transistor.

13. The semiconductor device according to claim 11, wherein
the board includes the first surface, a second surface facing the first surface, and an insulating layer between the first surface and the second surface, and
the first transistor and the second transistor are arranged in the insulating layer.

14. The semiconductor device according to claim 11, wherein
the first transistor has a first chip shape,
the second transistor has a second chip shape,
the light emitter has a third chip shape,
the light receiver has a fourth chip shape, and
when viewed from above, the fourth chip shape overlaps the first chip shape, the second chip shape, and the third chip shape.

15. The semiconductor device according to claim 11, further comprising:
a third transistor provided in the board; and
a fourth transistor provided in the board, and arranged in the first direction with respect to the third transistor.

16. The semiconductor device according to claim 15, wherein
the first transistor and the third transistor are arranged in line symmetry with respect to a line along the first direction, and
the second transistor and the fourth transistor are arranged in line symmetry with respect to a line along the first direction.

17. The semiconductor device according to claim 11, wherein
assuming that a direction above the first surface of the board is a second direction,
in the second direction, a length of the first spacer is equal to a length of the second spacer.

18. The semiconductor device according to claim 11, wherein
the light emitter includes a light emitting surface,
the light receiver includes a light receiving surface, and
the light receiving surface of the light receiver is arranged to face the light emitting surface of the light emitter.

19. The semiconductor device according to claim 11, wherein
the first spacer and the second space contain at least one of copper and an alloy.

20. The semiconductor device according to claim 15, wherein
a first signal is transmitted via the first transistor and the second transistor, and
a second signal, which is an inverted signal of the first signal, is transmitted via the third transistor and the fourth transistor.
